(19) United States
(12) Patent Application Publication
(10) Pub. No.: US 2022/0011670 A1
(43) Pub. Date: Jan. 13, 2022

(54) RESIST UNDERLAYER SURFACE MODIFICATION

(71) Applicant: International Business Machines Corporation, Armonk, NY (US)

(72) Inventors: Jing Guo, Niskayuna, NY (US); Dario Goldfarb, Dobbs Ferry, NY (US); Ekmini Anuja De Silva, Slingerlands, NY (US)

(21) Appl. No.: 16/923,228

(22) Filed: Jul. 8, 2020

(51) Int. Cl. G03F 7/11; G03F 7/004; G03F 7/38; G03F 7/09; G03F 7/075; G03F 7/32

(52) U.S. Cl. CPC G03F 7/11; G03F 7/0045; G03F 7/38; G03F 7/0752; G03F 7/0755; G03F 7/322; G03F 7/091

(57) ABSTRACT

Embodiments of the present invention are directed to resist underlayer surface modifications. In a non-limiting embodiment of the invention, a photoresist patterning stack includes a resist underlayer on a substrate. The resist underlayer includes a surface modification having one or more moieties. The moieties can include acid quencher moieties that limit acid diffusion during a post exposure bake. The acid quencher moieties can include a tert-butoxycarbonyl protecting group (tBOC)-blocked amine that can be copolymerized with an acid generating underlayer. The moieties can also include base-catalyzed crosslinking moieties selected such that base-catalyzed crosslinking can occur upon exposure to a predetermined developer. The base-catalyzed crosslinking moieties can include an acetal group and the predetermined developer can include tetramethylammonium hydroxide (TMAH).

### BACKGROUND

The present invention generally relates in general to fabrication methods and resulting structures for semiconductor devices. More specifically, the present invention relates to resist underlayer surface modifications to improve pattern fidelity for trench and via patterning.

Traditional CMOS (Complementary Metal Oxide Semiconductor) fabrication techniques include process flows for constructing planar transistors. The density of planar transistors can be increased by decreasing the pitch between transistor gate elements. However, the ability to decrease gate pitch in planar transistors is limited by the required gate length and spacer thickness. Nonplanar transistor architectures, such as vertical field effect transistors (VFETs) and stacked nanotube field effect transistors (FETs), employ semiconductor channels with various gate-all-around (GAA) technologies to achieve increased device density, greater power efficiency, and some increased performance over lateral devices. Photolithography is the predominant technique used to pattern these ultrafine structures. Photolithography techniques involve the patterning of a thin photoresist layer and the transfer of the resulting photoresist pattern into a substrate.

### SUMMARY

Embodiments of the present invention are directed to a method for resist underlayer surface modification. A non-limiting example of the method includes modifying an underlayer to include acid quencher precursors. The underlayer can be coated with a photoresist. The method can include generating acid quencher moieties by subjecting the photoresist to a post exposure bake that thermally activates the acid quencher precursors. Acid diffusion during the post exposure bake is limited by the acid quencher moieties.

Embodiments of the present invention are directed to a method for resist underlayer surface modification. A non-limiting example of the method includes modifying an underlayer to include base-catalyzed crosslinking moieties. The base-catalyzed crosslinking moieties can be selected such that base-catalyzed crosslinking can occur upon exposure to a predetermined developer. The underlayer can be coated with a photoresist and the photoresist can be subjected to the predetermined developer to crosslink the underlayer.

Embodiments of the invention are directed to resist underlayer surface modifications. A non-limiting example of a photoresist patterning stack includes a resist underlayer on a substrate. The resist underlayer can include a surface modification having one or more moieties. A photoresist can be formed on the resist underlayer. The moieties can include one or both of acid quencher moieties and base-catalyzed crosslinking moieties.

Additional technical features and benefits are realized through the techniques of the present invention. Embodiments and aspects of the invention are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the invention are apparent from the following detailed description taken in conjunction with the accompanying drawings in which:

FIG. 1 depicts a cross-sectional view of a semiconductor structure during an initial operation of a method of fabricating a semiconductor device according to one or more embodiments of the present invention;

FIG. 2 depicts a cross-sectional view of the semiconductor structure after a processing operation according to one or more embodiments of the invention;

FIG. 3 depicts a cross-sectional view of the semiconductor structure after a processing operation according to one or more embodiments of the invention;

FIG. 4 depicts a cross-sectional view of the semiconductor structure after a processing operation according to one or more embodiments of the invention;

FIG. 5 depicts a cross-sectional view of the semiconductor structure after a processing operation according to one or more embodiments of the invention;

FIG. 6 depicts two exemplary crosslinking formulas for base-catalyzed underlayer crosslinking with a resist during the develop process according to one or more embodiments of the invention;

FIG. 7 depicts a flow diagram illustrating a method according to one or more embodiments of the invention; and

FIG. 8 depicts a flow diagram illustrating a method according to one or more embodiments of the invention.

The diagrams depicted herein are illustrative. There can be many variations to the diagram or the operations described therein without departing from the spirit of the invention. For instance, the actions can be performed in a differing order or actions can be added, deleted or modified.

In the accompanying figures and following detailed description of the described embodiments, the various elements illustrated in the figures are provided with two or three digit reference numbers. With minor exceptions, the leftmost digit(s) of each reference number correspond to the figure in which its element is first illustrated.

### DETAILED DESCRIPTION

It is understood in advance that although example embodiments of the invention are described in connection with a simplified substrate structure for ease of discussion, embodiments of the invention are not limited to the particular substrate described in this specification. Rather, embodiments of the present invention are capable of being implemented to improve the lithographic patterning of semiconductor structures during any stage of fabrication, including the front-end-of-line (e.g., transistors, isolation structures) and back-end-of-line (e.g., vias and lines in a metallization layer).

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

Turning now to an overview of technologies that are more specifically relevant to aspects of the present invention, as previously noted herein, photolithography is the predominant technique used to pattern high-density planar and nonplanar transistor architectures such as vertical transport field effect transistors (VFETs) and stacked nanosheet field effect transistors (NSFETs) as well as back-end-of-line metallization layers (e.g., interconnects, metal trenches, and metal-filled vias). The progressive decrease in these device feature sizes and steady increase in device integration requirements have only increased the demands on photolithography. As semiconductor device critical dimensions continuously scale downward, device fabricators have turned to the development of improved patterning techniques, such as high-resolution multilayer photoresists and next generation lithography.

Several next generation lithography technologies have been proposed to satisfy patterning requirements beyond the 22 nm-node. Extreme ultraviolet (EUV) lithography is one of the candidates for the next generation of lithography. Some of the key challenges with EUV lithography is minimizing line width roughness (LWR) and preventing resist pattern collapse resulting from the small target critical dimensions (CD) and high aspect ratio requirements. In particular, next generation mask design is limited by resist printability and the resist thickness budget is limited by pattern collapse.

Turning now to an overview of aspects of the present invention, one or more embodiments of the invention provide a novel method for modifying underlayers to improve pattern fidelity (e.g., to reduce LWR and prevent pattern collapse) for trench and via patterning in next generation lithography. A first type of underlayer modification according to one or more embodiments includes the incorporation of acid quencher moieties (1 to 50 atomic percent) in the underlayer to prevent undercut and pattern lift off in the line/space patterns. A second type of underlayer modification according to one or more embodiments includes the use of moieties (e.g., acetal groups) that will undergo base-catalyzed crosslinking with the photoresist during the pattern development process, bolstering the strength of the line pattern. The acid quencher moieties and base-catalyzed crosslinking moieties can be used separately or together depending on the needs of a particular application. In some embodiments of the invention, the moieties are introduced at the surface of the underlayer at the interface with the photoresist. In other embodiments of the invention, the moieties are introduced throughout the underlayer to simplify underlayer preparation.

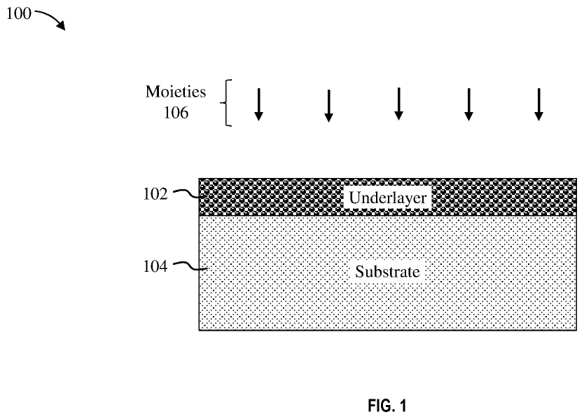

Turning now to a more detailed description of aspects of the present invention, FIG. 1 depicts a cross-sectional view of a semiconductor structure 100 during an initial operation of a method of fabricating a semiconductor device according to one or more embodiments of the invention. As depicted in FIG. 1, the semiconductor structure 100 can include an underlayer 102 formed over a substrate 104.

The substrate 104 can be made of any suitable substrate material, such as, for example, monocrystalline Si, silicon germanium (SiGe), III-V compound semiconductor, II-VI compound semiconductor, or semiconductor-on-insulator (SOI). Group III-V compound semiconductors, for example, include materials having at least one group III element and at least one group V element, such as one or more of aluminum gallium arsenide (AlGaAs), aluminum gallium nitride (AlGaN), aluminum arsenide (AlAs), aluminum indium arsenide (AlIAs), aluminum nitride (AlN), gallium antimonide (GaSb), gallium aluminum antimonide (GaAlSb), gallium arsenide (GaAs), gallium arsenide antimonide (GaAsSb), gallium nitride (GaN), indium antimonide (InSb), indium arsenide (InAs), indium gallium arsenide (InGaAs), indium gallium arsenide phosphide (InGaAsP), indium gallium nitride (InGaN), indium nitride (InN), indium phosphide (InP) and alloy combinations including at least one of the foregoing materials. The alloy combinations can include binary (two elements, e.g., gallium (III) arsenide (GaAs)), ternary (three elements, e.g., InGaAs) and quaternary (four elements, e.g., aluminum gallium indium phosphide (AlInGaP)) alloys.

In some embodiments of the invention, the substrate 104 can include a buried oxide layer (not shown) in a silicon-on-insulator (SOI) configuration. The buried oxide layer can be made of any suitable dielectric material, such as, for example, a silicon oxide. In some embodiments of the invention, the buried oxide layer is formed to a thickness of about 10-200 nm, although other thicknesses are within the contemplated scope of the invention. In some embodiments of the invention, the semiconductor structure 100 can also be formed without the buried oxide layer. In that case, an STI (shallow trench isolation) will be formed to isolate device from device.

In some embodiments of the invention, the underlayer 102 is an absorbing, photoimageable, and aqueous developable positive or negative image-forming antireflective coating composition that includes a non-crosslinked base polymer. In some embodiments of the invention, the underlayer 102 is an acid generating underlayer. In some embodiments of the invention, the base polymer of the antireflective coating includes any known materials suitable for a bottom antireflective coating (BARC). For example, the underlayer 102 can include a low temperature oxide (LTO), SiARC, TiARC, or SiON, although other underlayer materials are within the scope of the disclosure. In some embodiments of the invention, the molecular weight of the base polymer is in a range from about 1000 to about 20000 kg/kmol, although other molecular weights are within the contemplated scope of the invention. The underlayer 102 can be formed on the substrate 102 using any suitable process, such as, for example, grafting or spin coating.

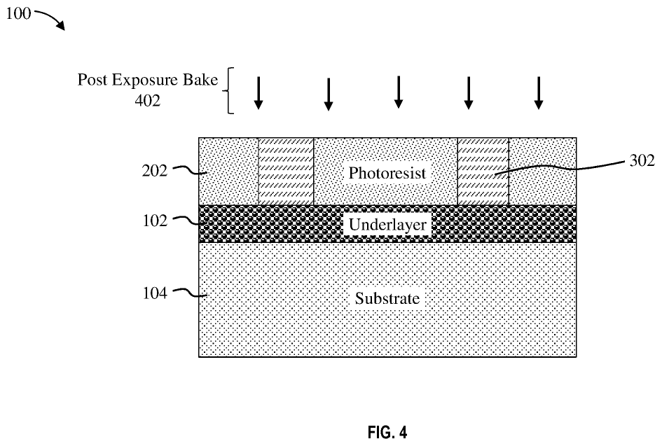

In some embodiments of the invention, the base polymer is modified by introducing moieties 106 (sometimes referred to as functional groups). The moieties 106 can be incorporated into the underlayer 102 before (e.g., chemically), during (e.g., in-situ), or after (e.g., thermally generated or activated during bake, discussed herein with respect to FIG. 4) forming the underlayer 102 on the substrate 104. In some embodiments of the invention, the moieties 106 are functional groups added to the base polymer of the underlayer 102. For example, in some embodiments of the invention, the moieties 106 are copolymerized with an acid generating compound, molecule or polymer of the underlayer 102. In some embodiments of the invention, the moieties 106 include acid quencher moieties or acid quencher precursors (inactivated acid quencher moieties). Suitable acid quencher moieties include compounds such as amines or polyamines, as well as quaternary ammonium compounds, trialkylammonium compounds, amides, and ureas. In some embodiments of the invention, the moieties 106 include tert-butoxycarbonyl protecting group (tBOC)-blocked amines that can be copolymerized with an acid generating underlayer. In some embodiments of the invention, the acid quencher moieties are incorporated within the underlayer 102 at a concentration of 1 to 50 atomic percent, such as, for example, 5 to 20 atomic percent.

As discussed previously, in some embodiments of the invention, the underlayer 102 is an acid generating underlayer. Acid generating underlayers offer improved scumming over basic underlayers but are known to cause pattern collapse in line/space areas. Conventionally, fabricators would balance the patterning requirements of a particular application (fidelity vs. pattern collapse) when choosing the underlayer acidity or basicity. Advantageously, the combination of an acid generating underlayer with acid quencher moieties improves surface adhesion during patterning (e.g., for line spacer and vias) without causing pattern collapse. In other words, the combination of an acid generating underlayer with acid quencher moieties allows fabricators to rely on an acidic underlayer to improve scumming while also mitigating pattern collapse, undercutting, and lift off in line/space areas due to the presence of the acid quencher moieties.

In some embodiments of the invention, the moieties 106 include base-catalyzed crosslinking moieties. In some embodiments of the invention, the base-crosslinking moieties are selected based on the developer such that the base-crosslinking moieties will undergo base-catalyzed crosslinking with a photoresist during the pattern development process. Suitable base-crosslinking moieties include acetal groups, which will undergo base-catalyzed crosslinking when developed with the developer tetramethylammonium hydroxide (TMAH). In some embodiments of the invention, the base-catalyzed crosslinking moieties are incorporated within the underlayer 102 at a concentration of 1 to 50 atomic percent, such as, for example, 5 to 20 atomic percent.

Crosslinking the underlayer and photoresist can bolster the via/line space pattern and can improve resist removal in mask-exposed areas during lithographic patterning. Conventionally, fabricators have relied upon a post exposure bake (PEB) thermal crosslinking of the underlayer and photoresist. Unfortunately, this thermal crosslinking process can fail to fully crosslink the underlayer to the photoresist. Partial crosslinking can result when the PEB temperature and duration is not within an ideal crosslinking range, as thermal crosslinking is highly dependent on the PEB conditions used in a particular application.

Advantageously, the presence of base-catalyzed crosslinking moieties allows for the underlayer and photoresist to crosslink during the develop process. In some embodiments of the invention, the underlayer and photoresist will not be crosslinked during the PEB; instead, crosslinking can occur solely during development. Freeing the PEB from thermal crosslinking requirements removes PEB processing constraints. In other embodiments of the invention, the underlayer and photoresist will undergo thermal crosslinking during the PEB and base-catalyzed crosslinking during development. In this manner, thermal and base-catalyzed crosslinking together help ensure full crosslinking between the underlayer and photoresist.

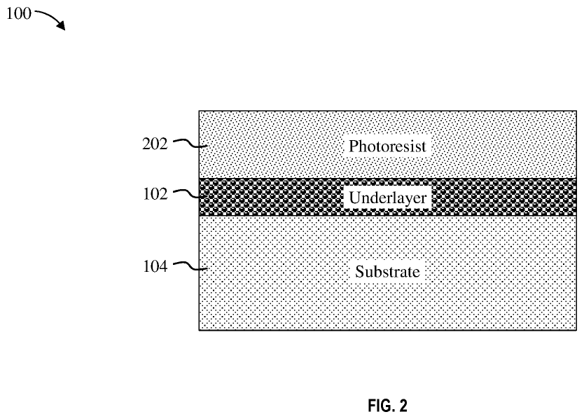

FIG. 2 depicts a cross-sectional view of the semiconductor structure 100 during an intermediate operation of a method of fabricating a semiconductor device according to one or more embodiments of the invention. In some embodiments of the invention, a photoresist 202 is formed directly on the underlayer 102. In some embodiments of the invention, the moieties 106 partially diffuse into the photoresist 202 at the interface between the underlayer 102 and the photoresist 202. In some embodiments of the invention, diffusion of the moieties 106 is limited or does not occur. In some embodiments of the invention, the photoresist 202 includes a polymeric resin, a photoacid generator (PAG), and a base. In some embodiments of the invention, the molar concentration ratio of the base to the PAG is about 0.2 to 1.5, although other concentrations are within the contemplated scope of the disclosure.

The polymeric resin can include any suitable resin binder composition, such as, for example, acrylate based polymers, methacrylate based polymers, hydroxy styrene based polymers, t-BOC p-hydroxy styrene/p-hydroxy styrene copolymers, t-butyl acrylate/p-hydroxy styrene copolymers, t-butylacrylate/p-hydroxystyrene/styrene terpolymers, cycloolefin based polymers, novalacs, and hexafluoroisopropanol (HFIP) styrene base polymers.

The PAG can include any suitable chemical or compound known to generate acid in response to radiant energy, such as, for example, onium salts, triphenylsulfonium salts, sulfonium salts, iodonium salts, diazonium salts, ammonium salts, 2,6-nitrobenzylesters, 1, 2, 3-tri(methanesulfonyloxy)benzene, sulfosuccinimides and photosensitive organic halogen compounds. In some embodiments of the invention, the PAG is reactive (responsive) to radiant energy at a wavelength of equal to or less than 455 nm, such as, for example, at one or more wavelengths or energies such as 248 nm, 193 nm, 157 nm, EUV, x-rays, e-beam (high or low voltage e-beam), and/or ion beam. In some embodiments of the invention, the PAG is soluble in the chosen polymeric resin. In some embodiments of the invention, the concentration of the PAG is about 0.01 percent to about 50 percent, for example between 1 percent and 10 percent, based on the total weight of the photoresist composition.

The base can include any suitable chemical or compound, such as, for example, primary, secondary, tertiary, and quaternary amines. In some embodiments of the invention, the base includes one or more of tetramethylammonium hydroxide, tetrabutylammonium hydroxide, tetraethanol ammonium hydroxide, 1,4-diazabicylo[2.2.2]octane, 1,5-diazabicyclo[4.3.0]non-5-ene, diazabicyclo[5.4.0]undec-7-ene, triphenyl amine, diphenyl amine, trioctyl amine, triheptyl amine, hexamethylenetetramine, hexamethylenetriethylenetetramine, N-diethyl-N′methylenediamine, 4-aminophenol, 2-(4-aminophenyl)-2-(4-hydroxyphenyl) propane, polystyrene, polyethylene, polyacrylate, polyamide, polyether, polyester, poly(N-acetylethylenimine), polyurethane, polyoxazoline, or a combination thereof.

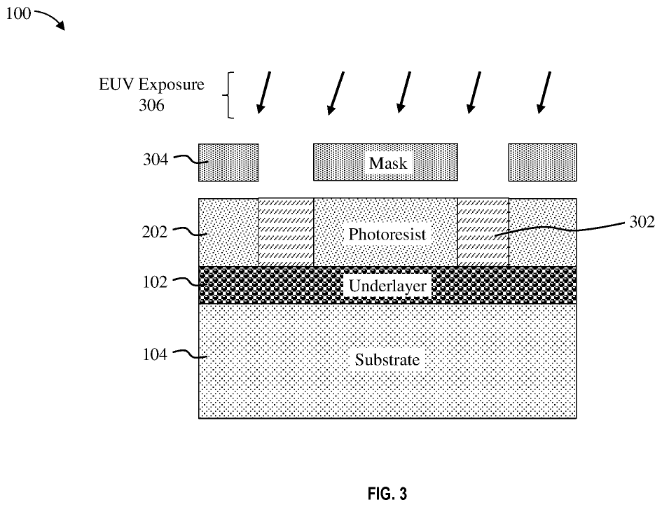

FIG. 3 depicts a cross-sectional view of the semiconductor structure 100 during an intermediate operation of a method of fabricating a semiconductor device according to one or more embodiments of the invention. In some embodiments of the invention, subsequent to coating the underlayer 102 with the photoresist 202, the semiconductor structure 100 is exposed to a source of activating radiation, which causes a chemical transformation in exposed areas 302 of the photoresist 202. In some embodiments of the invention, a mask 304 (sometimes referred to as a photomask) that defines the exposed areas 302 is placed over the photoresist 202 prior to the exposure.

In some embodiments of the invention, the source of activating radiation is an extreme ultraviolet (EUV) exposure (e.g., EUV exposure 304). While FIG. 2 illustrates an EUV exposure, however, it is understood that a wide variety of energy sources, such as X-rays, low and high kV electrons, ion beams, and extended optical wavelengths, e.g., 248, 193, and 157 nm radiation can be employed for advanced sub-100 nm patterning.

FIG. 4 depicts a cross-sectional view of the semiconductor structure 100 during an intermediate operation of a method of fabricating a semiconductor device according to one or more embodiments of the invention. In some embodiments of the invention, the semiconductor structure 100 is subjected to a post exposure bake (PEB) 402. A bake following the exposure can serve to smooth the concentration profile of the product of the photoreaction via its diffusion. In short, the subsequently developed resist structures can have steeper and smoother sidewalls following the PEB.

In some embodiments of the invention, chemically amplified photoresists need the subsequent baking step to complete the photoreaction initiated during exposure. During the PEB, chemical amplification of the photoresist can allow thick resist films to be exposed at relatively low doses and yet still be developed at a high rate. As discussed previously herein, in some embodiments of the invention, thermal crosslinking of the underlayer and the photoresist can occur during the PEB. In some embodiments of the invention, thermal crosslinking alone is not sufficient to fully crosslink the underlayer and the photoresist.

In some embodiments of the invention, the PEB occurs at a temperature of 85 to 250 degrees Celsius, for example, 200 degrees Celsius, although other temperatures are within the contemplated scope of the disclosure. In some embodiments of the invention, the PEB lasts for a few seconds to several minutes, for example, 90 seconds, although other bake times are within the contemplated scope of the disclosure.

In some embodiments of the invention, the moieties 106 are acid quencher precursors (inactivated acid quencher moieties) and the PEB serves to thermally activate the moieties or to generate acid quencher moieties from the precursors. Advantageously, acid diffusion that would otherwise occur during the PEB is limited (quenched) by the presence of the activated acid quencher moieties. Preventing or limiting acid diffusion in this manner can prevent undercutting and lift off in the line/space patterns.

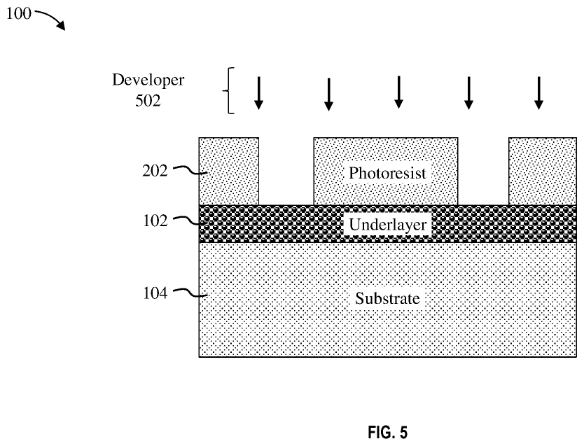

FIG. 5 depicts a cross-sectional view of the semiconductor structure 100 during an intermediate operation of a method of fabricating a semiconductor device according to one or more embodiments of the invention. In some embodiments of the invention, the semiconductor structure 100 is subjected to developer 502 following the PEB. In some embodiments of the invention, the developer 502 includes a developer solution that dissolves or otherwise removes either the radiation exposed areas 302 or the unexposed areas of the photoresist 202 (e.g., the masked portions), depending on whether the photoresist employed is a positive-type or negative-type photoresist, respectively. In some embodiments of the invention, the underlayer 102 is developable with the same developer 502 (e.g., an aqueous alkaline developing solution) used to develop the photoresist 202, thus forming a pattern in the underlayer 102 (not shown).

In some embodiments of the invention, the moieties 106 are base-catalyzed crosslinking moieties that crosslink with the photoresist 102 during exposure to the developer 502. As discussed previously herein, thermal crosslinking of the underlayer 102 and the photoresist 202 can be incomplete (or completely not present) and, advantageously, base-catalyzed crosslinking during development can help to ensure complete crosslinking. Improving the underlayer-photoresist crosslinking in this manner bolsters the strength of the line/via pattern, for example, by improving crosslinking of the line space.

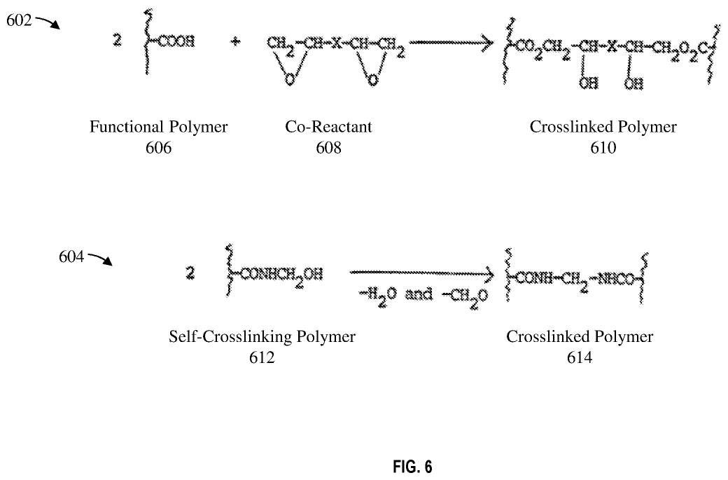

FIG. 6 depicts two exemplary crosslinking formulas 602 and 604, respectively, for enabling base-catalyzed underlayer crosslinking with a resist during the develop process according to one or more embodiments of the present invention. As depicted in FIG. 6, the first crosslinking formula 602 depicts the crosslinking of a functional polymer 606 (R—COOH) in the presence of a co-reactant 608. The result is a crosslinked polymer 610. In some embodiments of the invention, the functional polymer 606 includes a functional group that is selected such that it will crosslink in the presence of a developer. For example, if tetramethylammonium hydroxide (TMAH) is selected for the developer, the functional polymer 606 can include acetal functional groups that will crosslink with TMAH in the presence of the co-reactant 608.

As further shown in FIG. 6, the second crosslinking formula 604 depicts the self-crosslinking of a functional polymer 612 without requiring the presence of a co-reactant. The result is a crosslinked polymer 614. In some embodiments of the invention, the self-crosslinking polymer 612 includes a functional group that is selected such that it is self-reactive and will self-crosslink in the presence of a developer. For example, the self-crosslinking polymer 612 (R—CONHCH₂OH) will self-crosslink in the presence of TMAH.

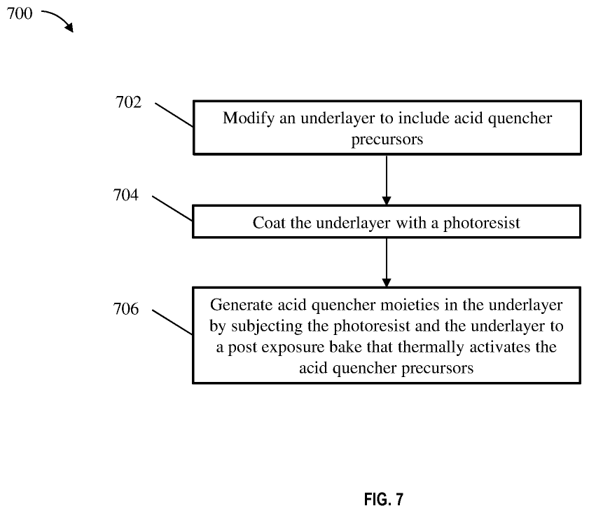

FIG. 7 depicts a flow diagram 700 illustrating a method for forming a semiconductor device according to one or more embodiments of the invention. As shown at block 702, an underlayer is modified to include acid quencher precursors. In some embodiments of the invention, the underlayer includes one or more of a low temperature oxide (LTO), a silicon based antireflective coating (SiARC), a titanium based ARC (TiARC), and silicon oxynitride (SiON).

At block 704, the underlayer is coated with a photoresist. At block 706, acid quencher moieties are generated in the underlayer by subjecting the photoresist and the underlayer to a post exposure bake that thermally activates the acid quencher precursors. In some embodiments of the invention, the acid quencher moieties are generated at the interface between the underlayer and the photoresist. In some embodiments of the invention, acid diffusion during the post exposure bake is limited by the acid quencher moieties. In some embodiments of the invention, the post exposure bake occurs at a temperature of 100 to 250 degrees Celsius for a duration of 1 to 300 seconds.

In some embodiments of the invention, the acid quencher moieties include one or more of an amine, polyamine, quaternary ammonium compound, trialkylammonium compound, amide, and urea. In some embodiments of the invention, the acid quencher moieties include a tert-butoxycarbonyl protecting group (tBOC)-blocked amine that can be copolymerized with an acid generating underlayer. In some embodiments of the invention, the acid quencher moieties are incorporated within the underlayer at a concentration of 5 to 20 atomic percent.

The method can further include exposing the photoresist to a source of activating radiation. In some embodiments of the invention, the activating radiation comprises one or more of an EUV exposure, an X-ray exposure, a low kV electron exposure, a high kV electron exposure, an ion beam exposure, and an optical exposure.

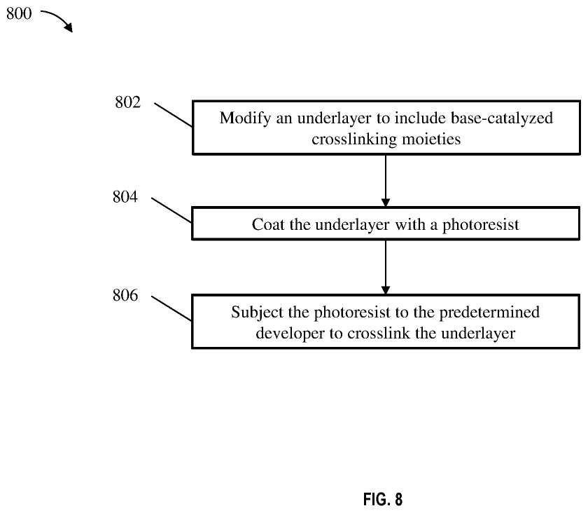

FIG. 8 depicts a flow diagram 800 illustrating a method for forming a semiconductor device according to one or more embodiments of the invention. As shown at block 802, an underlayer is modified to include base-catalyzed crosslinking moieties. In some embodiments of the invention, the underlayer includes one or more of a low temperature oxide (LTO), a silicon based antireflective coating (SiARC), a titanium based ARC (TiARC), and silicon oxynitride (SiON). In some embodiments of the invention, the base-catalyzed crosslinking moieties are selected such that base-catalyzed crosslinking can occur upon exposure to a predetermined developer.

At block 804, the underlayer is coated with a photoresist. At block 806, the photoresist is subjected to the predetermined developer to crosslink the underlayer.

The method can include subjecting the photoresist to a post exposure bake prior to developer exposure. In some embodiments of the invention, the post exposure bake occurs at a temperature of 100 to 250 degrees Celsius for a duration of 1 to 300 seconds. In some embodiments of the invention, a portion of the underlayer thermally crosslinks during the post exposure bake. In some embodiments of the invention, thermal crosslinking is partial or otherwise incomplete.

In some embodiments of the invention, the base-catalyzed crosslinking moieties include an acetal group and the predetermined developer includes tetramethylammonium hydroxide (TMAH). In some embodiments of the invention, the base-catalyzed crosslinking moieties include a functional polymer that crosslinks with a co-reactant in the presence of the predetermined developer. In some embodiments of the invention, the base-catalyzed crosslinking moieties include a self-crosslinking polymer that self-crosslinks in the presence of the predetermined developer.

Various embodiments of the present invention are described herein with reference to the related drawings. Alternative embodiments can be devised without departing from the scope of this invention. Although various connections and positional relationships (e.g., over, below, adjacent, etc.) are set forth between elements in the following description and in the drawings, persons skilled in the art will recognize that many of the positional relationships described herein are orientation-independent when the described functionality is maintained even though the orientation is changed. These connections and/or positional relationships, unless specified otherwise, can be direct or indirect, and the present invention is not intended to be limiting in this respect. Similarly, the term “coupled” and variations thereof describes having a communications path between two elements and does not imply a direct connection between the elements with no intervening elements/connections between them. All of these variations are considered a part of the specification. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e. one, two, three, four, etc. The terms “a plurality” are understood to include any integer number greater than or equal to two, i.e. two, three, four, five, etc. The term “connection” can include an indirect “connection” and a direct “connection.”

References in the specification to “one embodiment,” “an embodiment,” “an example embodiment,” etc., indicate that the embodiment described can include a particular feature, structure, or characteristic, but every embodiment may or may not include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements.

Spatially relative terms, e.g., “beneath,” “below,” “lower,” “above,” “upper,” and the like, are used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device can be otherwise oriented (e.g., rotated 90 degrees or at other orientations), and the spatially relative descriptors used herein should be interpreted accordingly.

The terms “about,” “substantially,” “approximately,” and variations thereof, are intended to include the degree of error associated with measurement of the particular quantity based upon the equipment available at the time of filing the application. For example, “about” can include a range of ±8% or 5%, or 2% of a given value.

The phrase “selective to,” such as, for example, “a first element selective to a second element,” means that the first element can be etched and the second element can act as an etch stop.

The term “conformal” (e.g., a conformal layer) means that the thickness of the layer is substantially the same on all surfaces, or that the thickness variation is less than 15% of the nominal thickness of the layer.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases can be controlled and the system parameters can be set so that the depositing atoms arrive at the deposition surface of the semiconductor substrate with sufficient energy to move about on the surface such that the depositing atoms orient themselves to the crystal arrangement of the atoms of the deposition surface. An epitaxially grown semiconductor material can have substantially the same crystalline characteristics as the deposition surface on which the epitaxially grown material is formed. For example, an epitaxially grown semiconductor material deposited on a {100} orientated crystalline surface can take on a {100} orientation. In some embodiments of the invention of the invention, epitaxial growth and/or deposition processes can be selective to forming on semiconductor surface, and may or may not deposit material on exposed surfaces, such as silicon dioxide or silicon nitride surfaces.

As previously noted herein, for the sake of brevity, conventional techniques related to semiconductor device and integrated circuit (IC) fabrication may or may not be described in detail herein. By way of background, however, a more general description of the semiconductor device fabrication processes that can be utilized in implementing one or more embodiments of the present invention will now be provided. Although specific fabrication operations used in implementing one or more embodiments of the present invention can be individually known, the described combination of operations and/or resulting structures of the present invention are unique. Thus, the unique combination of the operations described in connection with the fabrication of a semiconductor device according to the present invention utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), chemical-mechanical planarization (CMP), and the like. Reactive ion etching (ME), for example, is a type of dry etching that uses chemically reactive plasma to remove a material, such as a masked pattern of semiconductor material, by exposing the material to a bombardment of ions that dislodge portions of the material from the exposed surface. The plasma is typically generated under low pressure (vacuum) by an electromagnetic field. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photoresist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

The flowchart and block diagrams in the Figures illustrate possible implementations of fabrication and/or operation methods according to various embodiments of the present invention. Various functions/operations of the method are represented in the flow diagram by blocks. In some alternative implementations, the functions noted in the blocks can occur out of the order noted in the Figures. For example, two blocks shown in succession can, in fact, be executed substantially concurrently, or the blocks can sometimes be executed in the reverse order, depending upon the functionality involved.

The descriptions of the various embodiments of the present invention have been presented for purposes of illustration, but are not intended to be exhaustive or limited to the embodiments described. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A method for forming a semiconductor device, the method comprising:
modifying an underlayer to include acid quencher precursors;
coating the underlayer with a photoresist; and
generating acid quencher moieties in the underlayer by subjecting the photoresist and the underlayer to a post exposure bake that thermally activates the acid quencher precursors;
wherein acid diffusion during the post exposure bake is limited by the acid quencher moieties.

2. The method of claim 1, wherein the acid quencher moieties include one or more of an amine, polyamine, quaternary ammonium compound, trialkylammonium compound, amide, and urea.

3. The method of claim 1, wherein the acid quencher moieties include a tert-butoxycarbonyl protecting group (tBOC)-blocked amine that can be copolymerized with an acid generating underlayer.

4. The method of claim 1, wherein the acid quencher moieties are incorporated within the underlayer at a concentration of 5 to 20 atomic percent.

5. The method of claim 1 further comprising exposing the photoresist to a source of activating radiation.

6. The method of claim 5, wherein the activating radiation comprises one or more of an extreme ultraviolet (EUV) exposure, an X-ray exposure, a low kV electron exposure, a high kV electron exposure, an ion beam exposure, and an optical exposure.

7. The method of claim 1, wherein the post exposure bake occurs at a temperature of 100 to 250 degrees Celsius for a duration of 1 to 300 seconds.

8. The method of claim 1, wherein the underlayer comprises one or more of a low temperature oxide (LTO), a silicon based antireflective coating (SiARC), a titanium based ARC (TiARC), and silicon oxynitride (SiON).

9. A method for forming a semiconductor device, the method comprising:
modifying an underlayer to include base-catalyzed crosslinking moieties, the base-catalyzed crosslinking moieties selected such that base-catalyzed crosslinking can occur upon exposure to a predetermined developer;
coating the underlayer with a photoresist; and
subjecting the photoresist to the predetermined developer to crosslink the underlayer.

10. The method of claim 9 further comprising subjecting the photoresist to a post exposure bake prior to developer exposure.

11. The method of claim 10, wherein the post exposure bake occurs at a temperature of 100 to 250 degrees Celsius for a duration of 1 to 300 seconds.

12. The method of claim 10, wherein a portion of the underlayer thermally crosslinks during the post exposure bake.

13. The method of claim 9, wherein the base-catalyzed crosslinking moieties comprise an acetal group and the predetermined developer comprises tetramethylammonium hydroxide (TMAH).

14. The method of claim 9, wherein the base-catalyzed crosslinking moieties comprise a functional polymer that crosslinks with a co-reactant in the presence of the predetermined developer.

15. The method of claim 9, wherein the base-catalyzed crosslinking moieties comprise a self-crosslinking polymer that self-crosslinks in the presence of the predetermined developer.

16. A photoresist patterning stack comprising:
a resist underlayer on a substrate, the resist underlayer having a surface modification comprising one or more moieties, the moieties comprising one or both of acid quencher moieties and base-catalyzed crosslinking moieties; and
a photoresist formed on the resist underlayer.

17. The photoresist patterning stack of claim 16, wherein the acid quencher moieties limit acid diffusion during a post exposure bake.

18. The photoresist patterning stack of claim 17, wherein the acid quencher moieties include a tert-butoxycarbonyl protecting group (tBOC)-blocked amine that can be copolymerized with an acid generating underlayer.

19. The photoresist patterning stack of claim 16, wherein the base-catalyzed crosslinking moieties are selected such that base-catalyzed crosslinking can occur upon exposure to a predetermined developer.

20. The photoresist patterning stack of claim 19, wherein the base-catalyzed crosslinking moieties comprise an acetal group and the predetermined developer comprises tetramethylammonium hydroxide (TMAH).
